(19) United States
(12) Patent Application Publication
(10) Pub. No.: US 2014/0352764 A1
(43) Pub. Date: Dec. 4, 2014

(54) ROOF PANEL HAVING SOLAR CELL

(71) Applicant: HYUNDAI MOTOR COMPANY, Seoul (KR)

(72) Inventors: Won Jung Kim, Uiwang (KR); Sung Geun Park, Chuncheon (KR); Hae Yoon Jung, Seoul (KR); Sang Hak Kim, Uiwang (KR); Ji Yong Lee, Suwon (KR); Mi Yeon Song, Seoul (KR); Ki Chun Lee, Seoul (KR); Eun Young Lee, Seoul (KR)

(73) Assignee: HYUNDAI MOTOR COMPANY, Seoul (KR)

(21) Appl. No.: 14/109,129

(22) Filed: Dec. 17, 2013

(30) Foreign Application Priority Data
Jun. 4, 2013 (KR) 10-2013-0064144

(51) Int. Cl. H01L 31/048

(52) U.S. Cl. CPC H01L 31/0487
USPC 136/251

(57) ABSTRACT

A roof panel for a vehicle that has a solar cell is provided. Specifically, a solar cell panel that has a plurality of solar cell modules electrically connected is disposed on an inner surface of an upper surface of a vehicle body and a sticking member that protects the solar cell panel from an impact while having sticking characteristics is inserted and laminated between the inner surface of the upper surface of the vehicle body and the solar cell panel.

### CROSS-REFERENCE TO RELATED APPLICATION

This application claims under 35 U.S.C. §119(a) the benefit of Korean Patent Application No, 10-2013-0064144, filed on Jun. 4, 2013, the entire contents of which are incorporated herein by reference.

### BACKGROUND

(a) Technical Field

The present invention relates to a roof panel for a vehicle. More particularly, the present invention relates to a roof panel for a vehicle which includes a solar cell panel and has an anti-impact strength high enough to protect the solar cell panel from an impact.

(b) Background Art

In recent years, a technology has been developed of mounting a silicon solar cell panel to an upper surface (e.g., tempered glass of a sunroof or a panorama root) of a vehicle body of an eco-friendly vehicle such as a hybrid electric vehicle (HEV), an electric vehicle (EV), or a luxury vehicle to use electric power generated by a solar cell in the vehicle. For example, when an interior temperature of a vehicle increases during parking in the summer season, a fan is driven using electric power generated by a solar cell to allow the solar cell to be used as an eco-friendly energy source. Further, a comfortable feeling may be provided to passengers by lowering an interior temperature of the vehicle and thus fuel ratio may be improved by reducing consumption of an air conditioner.

However, since a conventional silicon solar cell is high-priced and opaque, it may not provide a natural open feeling when being installed in tempered glass of a sunroof forming an upper surface of the vehicle body. Accordingly, a next generation solar cell in which both an open feeling and an aerodynamic curve design are considered together and a sunroof for a vehicle employing the same are being expected to be developed. Further, since the sunroof for a vehicle to which a silicon solar cell is mounted is high-priced and increases the weight of the vehicle due to the weight of the panel, development of a solar cell for a vehicle which is relatively low-priced and lower in weight is important.

Among the next generation solar cells, a dye-sensitized solar cell, a thin film silicon solar cell, and an organic solar cell may be manufactured at lower manufacturing costs as compared to a silicon solar cell. Further, in the dye-sensitized solar cell various colors may be applied to the dye-sensitized solar cell. In particular, since the solar cell has a visual advantage by which an exterior and an interior of the solar cell may be viewed semi-transparently, it may be advantageously applied to a field requiring transparency as compared to a conventional silicon solar cell or other solar cells.

Since the substrates of a dye-sensitized solar cell and a thin film silicon solar cell generally use glass, an improved product value may be expected when it is disposed on an upper surface of a vehicle body such as a sunroof or a panorama roof of the vehicle. However, an anti-impact strength high enough to protect a solar cell panel from an impact is required when the solar cell panel is mounted to a roof panel for a vehicle, and a technology for securing an anti-impact strength of a panel has not been sufficiently developed when the solar cell is applied to a vehicle.

### SUMMARY

The present invention provides a roof panel for a vehicle which may include a solar cell panel and may have an anti-impact strength high enough to protect the solar cell panel from an impact.

In accordance with an aspect of the present invention, a roof panel for a vehicle having a solar cell, wherein when a solar cell panel or a solar cell panel in which a plurality of solar cell modules are electrically connected may be disposed on an inner surface of an upper surface of a vehicle body, a sticking member that protects the solar cell module or the solar cell panel from an impact while having sticking characteristics may be inserted and laminated between the inner surface of the upper surface of the vehicle body and the solar cell module or the solar cell panel.

According to an exemplary embodiment of the present invention, a finishing member may be attached to an inner surface of the solar cell module or the solar cell panel, and a separate sticking member that protects a solar cell panel from an external impact while maintaining sticking characteristics may be laminated between tempered glass and a solar cell panel.

According to another exemplary embodiment of the present invention, a bonding layer may be additionally laminated on one surface or opposite surfaces of the sticking member. Accordingly, the roof panel for a vehicle of the present invention may have improved anti-impact strength by which a solar cell may be sufficiently protected from an impact by inserting a sticking member between an upper surface of the vehicle body and a solar cell module or panel when the solar cell module or the solar cell panel is disposed on an inner surface of the upper surface of the vehicle body,

### BRIEF DESCRIPTION OF THE DRAWINGS

The above and other features of the present invention will now be described in detail with reference to certain exemplary embodiments thereof illustrated the accompanying drawings which are given hereinafter by way of illustration only, and thus are not limitative of the present invention, and wherein:

FIG. 1 is an exemplary sectional view showing a basic module structure of a dye-sensitized solar cell which is applicable to a roof panel for a vehicle according to an exemplary embodiment of the present invention;

FIG. 2 shows exemplary sectional views of roof panels for a vehicle according to various exemplary embodiments of the present invention;

FIG. 3 shows exemplary sectional views of a roof panel for a vehicle according to another exemplary embodiment of the present invention;

FIG. 4 is an exemplary sectional view showing a roof panel for a vehicle according to another exemplary embodiment of the present invention;

FIG. 5 is an exemplary view showing an application of a solar cell module to a sunroof of a vehicle according to an exemplary embodiment of the present invention; and

FIGS. 6A and 6B are exemplary views of a vehicle sunroof to which a solar cell module according to the exemplary embodiment of the present invention is mounted.

It should be understood that the accompanying drawings are not necessarily to scale, presenting a somewhat simplified representation of various exemplary features illustrative of the basic principles of the invention. The specific design features of the present invention as disclosed herein, including, for example, specific dimensions, orientations, locations, and shapes will be determined in part by the particular intended application and use environment. In the figures, reference numbers refer to the same or equivalent parts of the present invention throughout the several figures of the drawing.

### DETAILED DESCRIPTION

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles, fuel cell vehicles, and other alternative fuel vehicles (e.g., fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

Unless specifically stated or obvious from context, as used herein, the term “about” is understood as within a range of normal tolerance in the art, for example within 2 standard deviations of the mean. “About” can be understood as within 10%, 9%, 8%, 7%, 6%, 5%, 4%, 3%, 2%, 1%, 0.5%, 0.1%, 0.05%, or 0.01% of the stated value. Unless otherwise clear from the context, all numerical values provided herein are modified by the term “about.”

Hereinafter, exemplary embodiments of the present invention will be described in detail with reference to the accompanying drawings so that those skilled in the art can easily carry out the present invention. In a description of the exemplary embodiments of the present invention, the sizes of constituent elements may be exaggerated for clarity, and do not represent the actual sizes of the elements.

In the description of the exemplary embodiments of the present invention, a dye-sensitized solar cell will be basically described but is a simple example, and any solar cell that may be mounted to a support forming a general roof panel constituting an upper surface of a vehicle body or a roof panel such as glass of a sunroof/panorama roof may be applied to the present invention. In addition, any device that employs a smart window such as Electrochromic (EC), Polymer Dispersed Liquid Crystal (PDLC) and Suspended Particle Display (SPD) or a transparent electrode substrate or may be mounted to a vehicle, including an organic solar cell may be applied to the present invention.

Although a grid type parallel solar cell module in which cells are connected in parallel is illustrated, a monolithic structure in which photonic electrodes and catalytic electrodes of cells are formed in one substrate, a Z-type structure in which cells are connected in series, and a W-type structure in which photonic electrodes and catalytic electrodes are alternately formed in one substrate may be applied to the present invention in addition.

In the following description, inserting a metallic collector electrode is referred to as a module, and a solar cell in which such modules are connected in series or in parallel is referred to as a panel.

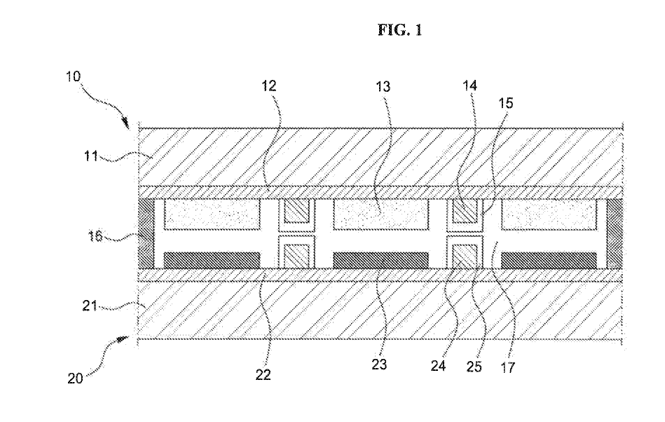

FIG. 1 is an exemplary sectional view showing a dye-sensitized solar cell that may be applied to a roof panel for a vehicle, and shows a basic configuration and structure of a parallel solar cell module in which cells may be connected in parallel. As shown, the dye-sensitized solar cell module unit cell) may include a working electrode 10 in which photonic electrodes to which a dye is adsorbed may be laminated, a counter electrode 20 in which catalytic electrodes 23 may be laminated, and an electrolyte 17 filled in a sealing space between the working electrode 10 and the counter electrode 20, and the working electrode 10 and the counter electrode 20 may be bonded with the electrolyte 17 therebetween. In particular, the working electrode 10 and the counter electrode 20 may include transparent substrates 11 and 21 on which transparent conductive oxides 12 and 22 such as Fluorine doped Tin Oxide (FTO), respectively to cause the generated photons to move.

In an interior of the solar cell module, that is, inside the space between the working electrode 10 and the counter electrode 20, a dye (not shown) may be disposed to absorb absorbing light and emit electrons, a photonic electrode (or a semiconductor oxide thin film) 13 such as titanium dioxide (TiO₂) may be laminated on the transparent conductive layer 12 of the transparent substrate 11 in the working electrode 10, and an electrolyte 17 may be disposed to fill electrons in the dye from which electrons are emitted.

A dye (e.g., a Ruthenium (Ru) based dye) that absorbs light may be adsorbed to a surface of the photonic electrode 13, which may include porous nano particles to move emitted electrons to an external electrode. A catalytic electrode 23 may be laminated on the transparent conductive layer 22 of the transparent substrate 21 in the counter electrode 20, and the counter electrode 20 that includes the catalytic electrode 23 may reduce the oxidized electrolyte 17. The catalytic electrode 23 may be a platinum (Pt) electrode operating as a catalytic, and may be located between metal electrode protection layers 25. A dye-sensitized solar cell module may be configured by filling the electrolyte 17 (e.g., an I⁻/I₃⁻ based electrolyte) in a space between electrodes sealed by a sealant 16 while the working electrode 10 and the counter electrode 20 are bonded to each other.

Further, since collection efficiency may deteriorate due to the resistance of the transparent conductive layer 12 and 22 when a size of the solar cell increases, the metallic collector electrodes 14 and 24 may be additionally inserted to compensate for the problem, and collector electrode protection layers 15 and 25 may be formed to prevent corrosion of the metallic collector electrodes 14 and 24 by the electrolyte.

As described above, the solar cell panel may be configured by inserting the metal collector electrodes 14 and 24 into solar cell modules and electrically connecting the solar cell modules in series or in parallel. The present invention provides a method and a structure for mounting a solar cell panel to an upper surface of a vehicle body, and a roof panel for a vehicle may be configured by attaching a solar cell panel to reinforcing glass of a sunroof or a panorama roof forming an upper surface of a vehicle body.

Further, the present invention provides a structure of improving an anti-impact strength of a solar cell roof panel for a vehicle, and a roof panel for a vehicle may be configured by inserting and stacking a sticking member that protects a solar cell panel from an external impact while maintaining sticking characteristics between tempered glass and a solar cell panel when the solar cell panel (or solar cell module) is disposed on an interior side of the vehicle, that is, on an inner surface of the tempered glass of a sunroof or a panorama roof

In applying the solar cell panel to the roof panel for a vehicle, the types of the transparent substrates 11 and 21 used for the working electrode 10 and the counter electrode 20 of the solar cell are not specifically limited according to an exemplary embodiment of the present invention, and may be a glass material for a solar cell such as soda lime glass, low-iron glass, or alkali-free glass or may be a known chemical tempered glass, heat strengthened glass, tempered glass, or general glass according to other characteristics thereof. In the present invention, a thickness of glass used for the transparent substrate 11 and 21 is not specifically limited, and ranges from ultra-thin glass that have a thickness of about 0.1 mm and glass of a thickness of several meters to be utilized according to their characteristics.

Moreover, considering that the solar cell panel may be attached to an interior side of the vehicle, when the substrate 11 and 21 is glass, glass of a minimal thickness may be used to maximize interior space, and a thickness of the solar cell panel may be decreased by using a thin film transparent substrate to minimize an increase in weight.

Soda lime glass may be used as a transparent substrate of a general dye-sensitized solar cell or specially made glass such as low-iron glass and alkali-free glass may be used to increase light transmission. Most of the glass transparent substrates generally have a thickness of about 2 mm or greater to endure an external impact, and have a minimum thickness of about 4 mm when a solar cell panel is manufactured. Further, tempered glass may be used as a glass material used for a sunroof or a panorama roof of a vehicle to secure safety of a passenger, and a general thickness of the tempered glass is about 4 mm. Thus, when a general solar cell panel is mounted, a roof panel for a vehicle may have a minimum thickness of about 8 mm, which increases the weight of the vehicle and lowers fuel ratio. Therefore, a transparent substrate of a solar cell panel used for a roof panel of a vehicle may have decreased thickness and weight.

A dye-sensitized solar cell that uses a lightweight thin film transparent substrate that has a substantially thin thickness may be mounted to the solar cell roof panel of the present invention, and specifically a thin film transparent substrate that has an ultraviolet ray transmission of at least 80% may be used. In particular, the thin film transparent substrate of the dye sensitized solar cell panel in the roof panel for a vehicle according to the exemplary embodiment of the present invention may have a thickness of about 1 mm or less, and the solar cell panel that uses the thin film transparent substrate may have a decreased thickness and a weight compared to a conventional substrate and may have a decreased weight and flexible characteristics suitable for attachment to tempered glass of a roof panel for a vehicle having a curved structure.

In addition, ultra-thin film glass that has flexible characteristics may be used as a thin film transparent substrate to naturally harmonize with a curved portion having a predetermined curvature, such as a sunroof or a panorama roof of a vehicle. The ultra-thin film transparent substrate formed of ultra thin film glass is a substrate thinner than a general transparent substrate and a thin film transparent substrate, and may have a thickness of about 0.7 mm or less and more preferably, may have a thickness of about 0.1 mm to 0.5 mm. Among flexible substrates, the ultra thin film transparent substrate that has a thin thickness may be transparent and may have improved surface flatness, therefore a separately introduced packaging thin film against moisture or oxygen may be omitted. Further, manufacturing costs may be reduced and process efficiency may be secured.

When a solar cell panel is configured by applying the ultra thin film transparent substrate that has a substantially thin thickness to a working electrode and a counter electrode, an entire thickness of the solar cell panel may be reduced to a thickness of about 2 mm or less may be formed compared to a conventional transparent substrate that has a thickness of about 4 mm or greater. Further, the solar cell panel may be applied to the roof panel for a vehicle without changing the design of the vehicle, and manufacturing costs may be reduced.

Hereinafter, in the description of the exemplary embodiments of the present invention, the ultra thin film and thin film transparent substrates are thin film transparent substrates as the ultra thin film transparent substrate fall within the scope of the thin film transparent substrate.

A thin film plastic substrate of a polymer material may be applied as the thin film transparent substrate of the solar cell panel in addition to the glass substrate and a plastic substrate that has an ultraviolet ray transmission of at least 80% may be used. Further, for a plastic substrate, a transparent substrate that has a thickness of about 0.1 mm to 1 mm may be used.

The plastic substrate may be a substrate manufactured using any one selected from a polyethylene based polymer, a polypropylene based polymer, a polyester based polymer, a polyacryl based polymer, a polyimide based polymer, a polystyrene based polymer, a substrate made of a blend where polymer materials are mixed or a copolymer, or a substrate made by laminating polymer materials. In particular, for example, polycarbonate (PC), polyethersulfone (PES), cyclic olefin copolymer (COC), polyethylene (PE), polyethyleneterephthalate (PET), polyehtylenenaphthalate (PEN), triacetylcellulose (TAC), polyimide (PI), polymethylmethacrylate (PMMA), polyetheretherketone (PEEK), polyamide (PA), polyetherimide (PEI), polypropylene (PP), and polypropylene (OPP, oriented) may be used.

Moreover, when the thin film transparent substrate is applied, the substrate may be damaged by an external impact and thus a structure for protecting the substrate is necessary. Accordingly, a solar cell module or a solar cell panel in which a plurality of solar cell modules are electrically connected may be disposed on an inside surface of temperature glass of a sunroof or a panorama roof to form an upper surface of the vehicle body in a roof panel of a vehicle according to the exemplary embodiment of the present invention, and a sticking member that protects a solar cell panel from an external impact while having sticking characteristics may be stacked between tempered glass of a sunroof or a panorama roof and a solar cell module or a solar cell panel.

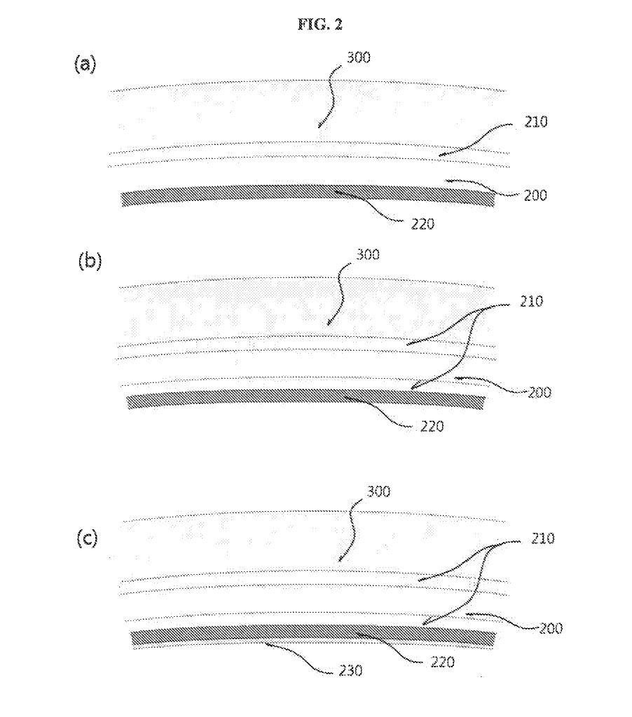

FIG. 2 shows exemplary sectional views of roof panels for a vehicle according to various exemplary embodiments of the present invention, and shows the exemplary embodiments of the present invention in which a solar cell panel 200 may be disposed while a sticking member 210 is stuck to an inside surface of the upper surface (tempered glass) 300 of the vehicle body. In addition, FIG. 2 shows the solar cell panel 200 while the elements of FIG. 1 are not illustrated for convenience. As shown in FIG. 1, in each of the modules of the solar cell panel 200, the counter electrode 20 (see FIG. 1) may be located below the working electrode 10 (see FIG. 1) to attach the solar cell panel 200 while the sticking member 210 is stuck to an inside surface of the upper surface 300 of the vehicle body.

Further, although FIG. 2 shows an exemplary curved shape of the solar cell panel 200 based on the curvature of the upper surface 300 of the vehicle body, a flat solar cell panel may be applied when the upper surface 300 of the vehicle body is not curved but flat. In section (a) of FIG. 2 a sticking member 210 may be interposed between an upper surface (e.g., glass of a sunroof or a panorama roof) 300 of the vehicle and the solar cell panel 200 and a finishing member 220 may be attached to an inner side of the solar cell panel 200, in which the finishing member 220 may be attached to an outer surface of the counter electrode (e.g., the transparent substrate of the counter electrode) 20 (see FIG. 1) of the solar cell panel 200. In some cases, the finishing member 220 may be removed.

Further, the sticking member 210 may be made of a flexible and cushioning material, and the sticking member 210 may protect the solar cell panel 200 when an impact is applied from the exterior through a proper impact absorbing operation. Thus, the sticking member 210 may increase anti-impact strengths of the solar cell panel 200 and the roof panel as a whole.

The sticking member 210 is not specifically limited, but may be a sticking member using one or more complex materials selected from a group consisting of polydimethylsiloxane (PDMS), polysilazane, polysilsesquioxane (PSSQ), a polysilicon based polymer, a polyurethane polymer, an epoxy based polymer, a synthetic resin, a natural rubber, a modified elastomer, a polyacryl based polymer such as polymethylmethacrylate (PMMA), a styrene based copolymer and a styrene based thermosetting copolymer such as polystyrene (PS), styrene-butadiene-styrene block copolymer (SBS), styrene-isoprene-styrene triblock copolymer (SIS), styrene-etylene-butylene-styrene block copolymer (SEBS), and acrylonitrile-butadiene-styrene copolymer (ABS), and a cellulose composite such as methylcellulose, ethylcellulose, and buthylcellulose, and polyvinylbutyral (PVB), ethylene vinyl acetate (EVA), and a sticking member obtained by laminating members formed of the above-described materials.

In the exemplary embodiment of section (a) of FIG. 2, a bonding film (e.g., finishing material) 220 may be formed on one surface which meets the counter electrode of the solar cell panel 200 to support the solar cell panel 200, and the bonding layer may be coated on opposite surfaces of the sticking member 210. The bonding film 220 may be obtained by forming a bonding layer on one surface of a polymer base, in which the base may be a film manufactured using a polymer material such as a polyethylene based polymer, a polypropylene based polymer, a polyester based polymer, a polyacryl based polymer, a polyimide based polymer, a polystyrene based polymer, may be a film formed of a blend where polymer materials are mixed or a copolymer, or a film obtained by laminating a plurality of polymer materials. However, the bonding film is not limited thereto.

The bonding layer of the bonding film may be formed using a material such as an epoxy based material, an acryl based material, a urethane based material, or a modified acryl based material, a modified urethane based material, and a modified elastomer based material, Further, after the bonding layer is formed at the working electrode and the counter electrode of the solar cell, the bonding layer may be bonded to the polymer base. In addition, instead of the bonding film, a support manufactured of a complex material in which PC (polycarbonate) or glass fibers are mixed, or EVA (Ethylene Vinyl Acetate), or glass, may be used, but any support formed of a material capable of supporting a solar cell or a sticking member may be used. In the present invention, the bonding film or the support will be referred to as a finishing member.

Section (h) of FIG. 2 shows an exemplary embodiment in which a sticking member 210 may be interposed between the solar cell panel 200 and the finishing member 220 as compared to section (a) of FIG. 2. As shown, the sticking member 210 may be laminated on opposite surfaces of the solar cell panel 200 to surround the solar cell panel 200 in a sandwich type, and may prevent damage to the solar cell panel 200 due to an internal or external impact of the vehicle. In addition, section (c) of FIG. 2 shows an exemplary embodiment in which a thermoplastic or UV curing protection coating layer 230 giving a surface strength to increase an anti-scratch property may be coated on a surface of the finishing member 220 exposed to the interior of a vehicle as compared with the exemplary embodiments of sections (a) and (b) of FIG. 2.

Table 1 is a simulation result obtained by calculating a maximum stress MPa applied to the solar cell substrate by an external impact when the sticking member using PDMS is applied, and soda lime thin film glass is used as the solar cell substrate.

TABLE 1

| | |
|---|---|
| | Maximum Stress of Solar Cell Substrate |
| Existence of | (MPa) |

| Sticking Member | Load Strength Test | Anti-impact Test |
|---|---|---|
| None | 80.5 | 97 |
| Present | 33.6 | 41.1 |

It is known in the art that the soda lime glass may be damaged when the maximum stress is 50 MPa or higher, and Table 1 shows that the solar cell panel is not damaged when a PDMS sticking, member of a predetermined thickness is applied (e.g., a maximum stress of less than 50 MPa is generated).

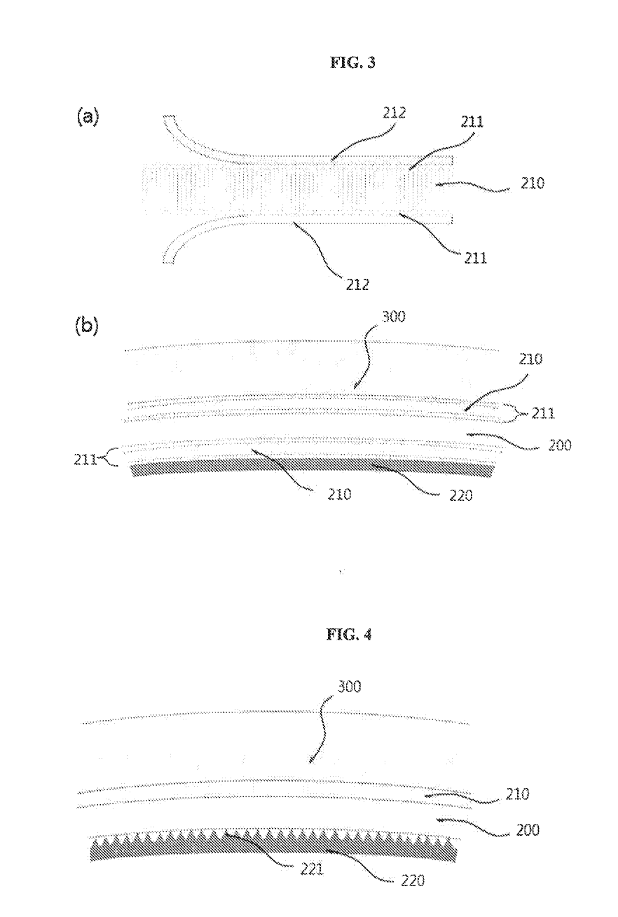

Moreover, a bonding layer may be laminated on one surface or opposite surfaces of the sticking member to constitute the roof panel for a vehicle. FIG. 3 is an exemplary sectional view showing a roof panel for a vehicle according to another exemplary embodiment of the present invention, and shows an exemplary embodiment in which the transparent bonding layer 211 is applied to opposite surfaces of the sticking member 210.

Specifically, section (a) of FIG. 3 is an exemplary sectional view of the sticking member 210 in which the bonding layer 211 may be formed, and section (b) of FIG. 3 is an exemplary sectional view of a roof panel using the sticking member 210 of section (a) of FIG. 3. The exemplary embodiment of section (b) of FIG. 3 may be different from the embodiment of sections (b) of FIG. 2 in that the bonding layer 211 may be additionally applied to opposite surfaces of the sticking member 210. In addition to the configurations of the exemplary embodiments shown in FIG. 2 a bonding layer 211 may be laminated on one surface or opposite surfaces of the sticking member 210 to constitute a roof panel.

When the transparent bonding layer 211 is bonded to the sticking member 210, the sticking member 210 may be stably bonded and fixed between the upper surface 300 of the vehicle and the solar cell panel 200 (or the solar cell module), and between the solar cell panel 200 and the finishing member 220 by the transparent bonding layer 211, and a bonding force between the sticking member 210 and the elements bonded to the sticking member 210 may be improved.

In addition, the sticking member 210 that has the transparent bonding layer 211 may be prepared while the release film 212 is attached on the bonding layer 211 for each treatment and process as shown in section (a) of FIG. 3, wherein when the sticking member 210 is bonded to other elements such as the upper surface 300 of the vehicle body, the solar cell panel 200, and the finishing member 220, the release film 212 may be removed from the bonding layer 211. The release film 212 may be manufactured from a general transparent film polymer material, and a highly releasing material such as a silicon based material or a fluorine based material may be coated on the release film to be released after being attached to the bonding layer to be used. An adhesive that may be used to form the bonding layer 211 may be an epoxy based material, an acryl based material, a urethane based material, a modified acryl based material, a modified urethane based material, or a modified elastomer based material. However, since the release film 212 may be a disposable film that protects a surface of the transparent bonding layer 211, a film of a low-priced material such as polyester may be used.

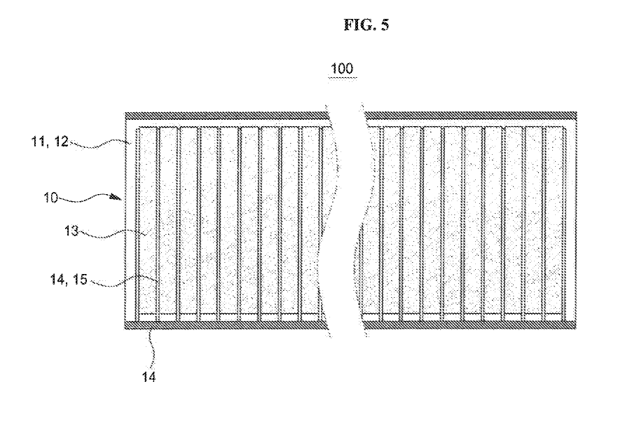

Moreover, FIG. 4 is an exemplary sectional view showing a roof panel according to another exemplary embodiment of the present invention. As shown, a scattering layer 221 may be additionally introduced to one surface of the solar cell panel protecting finishing member 220 that includes a transparent bonding film. When the scattering layer 221 is formed, light entering the solar cell panel 200 may be scattered in the solar cell panel and loss of light directly exiting to the exterior of the solar cell panel may be reduced, thereby increasing the efficiency of the solar cell. In other words, in the transparent bonding film which is the finishing member 220, the scattering layer 221 that scatters light having entered the solar cell panel 200 to reduce loss of light and increase efficiency of the solar cell may be provided on one surface of the transparent bonding film bonded to a substrate (e.g., the solar cell module or an inner surface of the solar cell panel) of the counter electrode. The scattering layer 221 of the film may be obtained by forming a convexo-concave structure that has a triangular pyramid such as a saw-tooth shape as shown in FIG. 4, or various beads that have different sizes may be formed such that a non-uniform structure whose surface has different heights may be formed in the transparent bonding layer.

Although not shown in the drawings, a light reflecting layer, such as aluminum foil or a mirror, that reflects light may be formed on one surface (e.g., a surface attached to an outer surface of the substrate for the counter electrode) of the transparent bonding film, which may achieve the same effect as forming the scattering layer. However, since the transparent bonding film that has the light reflecting layer may lower a lighting property when applied to a sunroof of the vehicle.

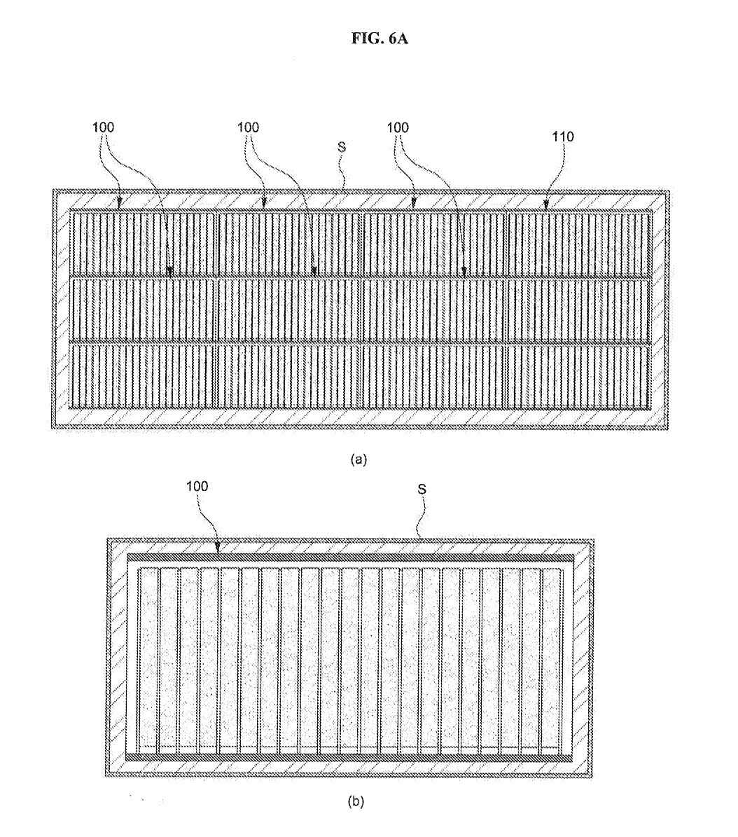

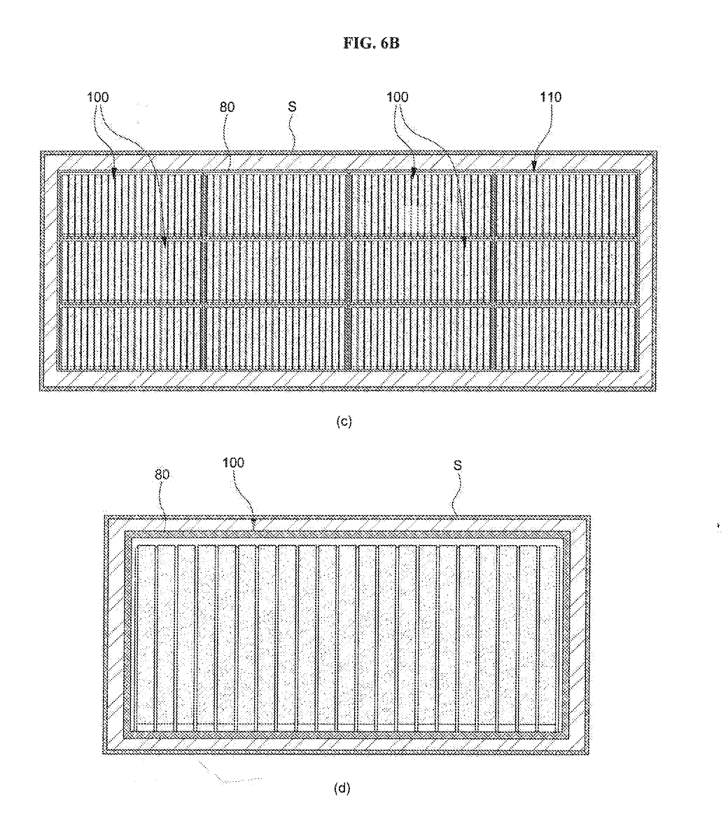

FIG. 5 is an exemplary view showing the solar cell module which has been described in the exemplary embodiments, and shows a surface of the solar cell module that has a parallel structure. In other words, FIG. 5 is an exemplary view of the solar cell module 100 from the top of the working electrode 10, and the portion viewed in the drawing is a working electrode contacting an upper surface of the vehicle body. Then, the counter electrode 20 may be located below the working electrode 10. When the roof panel (sunroof) of the vehicle according to the exemplary embodiment of the present invention is constituted using the solar cell module 100 shown, it appears like the form in section (b) of FIG. 6A.

The number of the solar cell modules 100 attached to the sunroof S according to the size of the sunroof S and the size of the solar cell module 100 attached to the sunroof S. One solar cell module 100 may be applied to an entire area of the sunroof S as in section (b) of FIG. 6A, or a solar cell array (e.g., solar cell panel) 110 in which a plurality of solar cell modules 100 may be applied to an entire area of the sunroof S as in section (a) of FIG. 6A.

When a plurality of solar cell modules 100 are connected as in section (a) of FIG. 6A, the solar cell modules 100 arranged longitudinally may be connected in series and the solar cell modules 100 arranged transversely may be connected in parallel. However, the connection form may be changed based on specifications such as an output, a voltage, and a current of the solar cell module. Further, as shown in sections (c) and (d) of FIG. 6B, a portion of the sunroof S of the vehicle other than an actual effective area (e.g., an area of a photonic electrode) of the solar cell module 100 may be masked to be attached to the manufactured solar cell module 100. The masking of the portion other than the actual effective area of the solar cell module 100 may be directly coated on the sunroof S or may be coated at a periphery of the solar cell module 100.

Although the exemplary embodiments of the present invention have been described in detail, the scope of the present invention is not limited thereto and various modifications and improvements of the present invention made by those skilled in the art also fall within the scope of the present invention.

What is claimed is:

1. A roof panel for a vehicle having a solar cell, comprising:
a solar cell panel having a plurality of solar cell modules electrically connected is disposed on an inner surface of an upper surface of a vehicle body; and
a sticking member that protects the solar cell panel from an impact while having sticking characteristics is inserted and laminated between the inner surface of the upper surface of the vehicle body the solar cell panel.

2. The roof panel of claim 1, wherein the solar cell panel further comprises:
a substrate which is a flexible glass or plastic substrate having a thickness of about 0.01 mm to 1 mm and is deflectable based on a curved shape of the upper surface of the vehicle body.

3. The roof panel of claim 2, wherein the plastic substrate may be a substrate manufactured using any one selected from a group consisting of: a polyethylene based polymer, a polypropylene based polymer, a polyester based polymer, a polyacryl based polymer, a polyimide based polymer, a polystyrene based polymer, a substrate made of a blend where polymer materials are mixed or a copolymer, and a substrate made by laminating polymer materials.

4. The roof panel of claim 2, wherein the substrate has an ultraviolet ray transmission of 80% or greater.

5. The roof panel of claim 1, further comprising:
a finishing member attached to an inner surface of the solar cell panel; and
a separate sticking member that protects a solar cell panel from an external impact while maintaining sticking characteristics is laminated between tempered glass and a solar cell panel.

6. The roof panel of claim 5, wherein the sticking member includes:
PDMS (Polydimethylsiloxane), Polysilazane, PSSQ (polysilsesquioxane), a polysilicon based polymer, a polyurethane polymer, an epoxy based polymer, a synthetic resin, a natural rubber, a modified elastomer, a polyacryl based polymer such as PMMA (Polymethylmethacrylate), a styrene based copolymer;
a styrene based thermosetting copolymer such as P1 (Polystyrene), SBS (Styrene-Butadiene-Styrene Block Copolymer), SIS (Styrene-Isoprene-Styrene Triblock Copolymer), SEBS (Styrene-Etylene-Butylene-Styrene Block Copolymer), and ABS (Acrylonitrile-Butadiene-Styrene Copolymer);
a cellulose composite such as methylcellulose, ethylcellulose, and buthylcellulose, and PVB (Polyvinylbutyral), EVA (Ethylene Vinyl Acetate); and
a sticking member obtained by laminating members formed of the materials.

7. The roof panel of claim 5, wherein a bonding layer is additionally laminated on one surface or opposite surfaces of the sticking member.

8. The roof panel of claim 1, wherein a finishing member is attached to an inner surface of the solar cell panel, and a scattering layer is formed on one surface of the finishing member bonded to an inner surface of the solar cell module or the solar cell panel.
